(19) United States
(12) Patent Application Publication
(10) Pub. No.: US 2025/0358543 A1
(43) Pub. Date: Nov. 20, 2025

(54) COMPARATOR AND IMAGE SENSOR INCLUDING THE SAME

(71) Applicant: Samsung Electronics Co., Ltd., Suwon-si (KR)

(72) Inventors: Seonju LEE, Suwon-si (KR); Daehwa PAIK, Suwon-si (KR); Jaehong KIM, Suwon-si (KR)

(73) Assignee: Samsung Electronics Co., Ltd., Suwon-si (KR)

(21) Appl. No.: 19/007,961

(22) Filed: Jan. 2, 2025

(30) Foreign Application Priority Data
May 16, 2024 (KR) 10-2024-0064043

(51) Int. Cl. H04N 25/772; H03F 3/08; H04N 25/709

(52) U.S. Cl. CPC H04N 25/772; H03F 3/082; H04N 25/709

(57) ABSTRACT

Provided is a comparator of an image sensor, the comparator including a first input transistor configured to receive a reference signal, a second input transistor configured to receive an input signal, a first load transistor configured to output a first output signal to a first output node based on a difference between the reference signal and the input signal, and a first cascode transistor coupled to the first input transistor and the first output node.

### CROSS-REFERENCE TO RELATED APPLICATION(S)

This application claims the benefit of Korean Patent Application No. 10-2024-0064043, filed on May 16, 2024, in the Korean Intellectual Property Office, the disclosure of which is incorporated herein by reference.

### BACKGROUND

### 1. Field of the Invention

Example embodiments relate to a comparator, and an image sensor including the same.

### 2. Description of the Related Art

Recently, ways to design the supply power of image sensors to be low voltage are being studied to reduce power consumption. The image sensor may include a comparator that compares analog input signals and converts them into digital signals. As the comparator operates normally with low-voltage supply power, a method to secure the input range of the comparator is required.

### SUMMARY

An aspect provides a comparator that operates normally at low voltage supply power, and an image sensor including the comparator.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

According to an aspect, there is provided a comparator of an image sensor, the comparator including a first input transistor configured to receive a reference signal, a second input transistor configured to receive an input signal, a first load transistor configured to output a first output signal to a first output node based on a difference between the reference signal and the input signal, and a first cascode transistor coupled to the first input transistor and the first output node.

According to another aspect, there is provided an image sensor that includes a pixel configured to output a pixel signal, a lamp generator configured to output a lamp signal, and a comparator configured to, based on an input signal corresponding to the pixel signal and a reference signal corresponding to the lamp signal, output a first output signal, the comparator including a first input transistor configured to receive a reference signal, a second input transistor configured to receive an input signal, a first load transistor configured to output a first output signal to a first output node based on a difference between the reference signal and the input signal, and a first cascode transistor coupled to the first input transistor and the first output node.

Additional aspects of example embodiments will be set forth in part in the description which follows and, in part, will be apparent from the description, or may be learned by practice of the disclosure.

According to example embodiments, it is possible to provide a comparator that operates normally at low voltage supply power, and an image sensor including the same. It is possible to provide a comparator with sufficient input range, and an image sensor including the same.

Effects of the present disclosure are not limited to those described above, and other effects may be made apparent to those skilled in the art from the following description.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a block diagram illustrating an image sensor according to an example embodiment;

FIG. 2 is a diagram for explaining the pixels and an analog digital converter (ADC) of an image sensor according to an example embodiment;

FIGS. 3A and 3B are diagrams for explaining the operation of a comparator according to the power supply according to some example embodiments;

FIG. 4A is a diagram for explaining a comparator according to an example embodiment;

FIG. 4B is a diagram for explaining a relationship of a reference signal and an input signal of a comparator by an auto-zero operation according to an example embodiment;

FIG. 5 is a circuit diagram illustrating a comparator according to an example embodiment;

FIG. 6 is a circuit diagram illustrating a comparator according to an example embodiment;

FIG. 7 is a circuit diagram illustrating a comparator according to an example embodiment; and

FIG. 8 is a circuit diagram illustrating a comparator according to an example embodiment.

### DETAILED DESCRIPTION

Terms used in the example embodiments are selected from currently widely used general terms when possible while considering the functions in the present disclosure. However, the terms may vary depending on the intention or precedent of a person skilled in the art, the emergence of new technology, and the like. Further, in certain cases, there are also terms arbitrarily selected by the applicant, and in the cases, the meaning will be described in detail in the corresponding descriptions. Therefore, the terms used in the present disclosure should be defined based on the meaning of the terms and the contents of the present disclosure, rather than the simple names of the terms.

Throughout the specification, when a part is described as “comprising or including” a component, it does not exclude another component but may further include another component unless otherwise stated. Furthermore, terms such as “ . . . unit” and “ . . . module” described in the specification mean a unit that processes at least one function or operation, which may be implemented as hardware including circuits.

Hereinafter, example embodiments of the present disclosure will be described in detail with reference to the accompanying drawings so that those of ordinary skill in the art to which the present disclosure pertains may easily implement them. However, the present disclosure may be implemented in multiple different forms and is not limited to the example embodiments described herein.

Hereinafter, example embodiments will be described in detail with reference to the drawings.

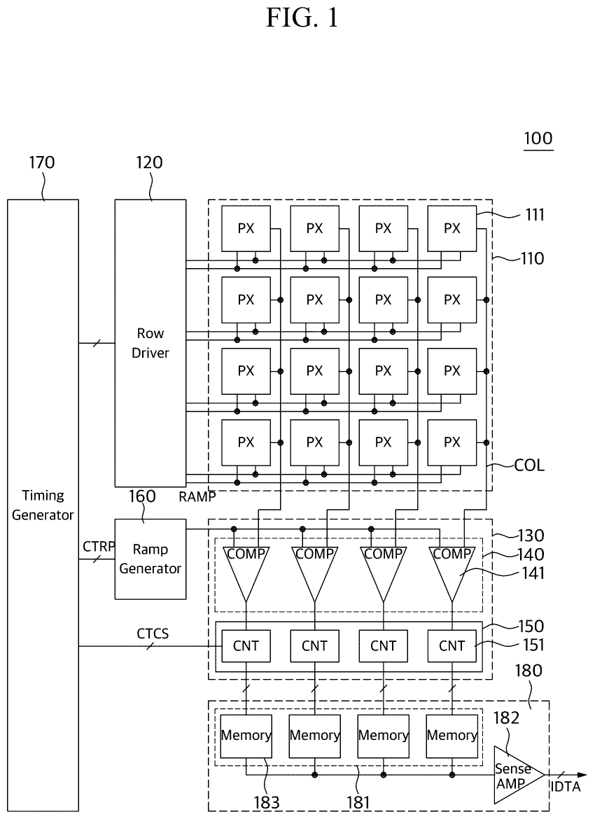

FIG. 1 is a block diagram illustrating an image sensor according to an example embodiment.

Referring to FIG. 1, an image sensor 100 may generate images by detecting light. The image sensor 100 may be mounted on various electronic devices such as cameras, smartphones, tablets, wearable devices, Internet of Things (IoT) devices, cars, black boxes and security camera systems.

The image sensor 100 may include a pixel array 110, a row driver 120, an ADC block 130, a lamp signal generator 160, a timing signal generator 170 and a buffer 180.

The pixel array 110 may be connected to the row driver 120 through multiple row lines, and be connected to the ADC block 130 through multiple column lines COLs. Each row line may represent one row, and each column line COL may represent one column.

The pixel array 110 may include a plurality of pixels 111. Each of the plurality of pixels 111 may be connected to one of the plurality of row lines, and may be connected to one of the plurality of column line COLs. The plurality of pixels 111 may be arranged in a matrix form according to rows and columns. The pixel 111 may include a light sensing element. For example, the photosensing device may include at least one of a photodiode, a phototransistor, and a pinned photodiode. The pixel 111 may detect incident light and convert it into a pixel signal, for example, an electrical signal. The pixel signal may be generated through a reset operation and a light detection operation of the pixel 111. The pixel signal may be an input signal compared to a lamp signal RAMP.

The timing signal generator 170 may control the operations of each of the row driver 120, the ADC block 130 and the lamp signal generator 160. For this purpose, the timing signal generator 170 may output a control signal or a clock signal to control the timing of the operation.

The row driver 120 may drive the pixel array 110 in row line units. In an example embodiment, the row driver 120 may simultaneously control the operation of pixels connected to the row line. For example, when a control signal (for example, an address signal) is received from the timing signal generator 170, the row driver 120 may output a selection signal through one row line corresponding to a control signal among a plurality of row lines. The plurality of pixels 111 connected to the row line through which the selection signal is transmitted may output a pixel signal through each column line.

The ADC block 130 may convert the pixel signal, which is an analog signal received from the pixel array 110, into a digital signal. In an example embodiment, the ADC block 130 may include a comparator block 140 and a counter block 150. The comparator block 140 may include a plurality of unit comparators 141. Each of the plurality of unit comparators 141 may be connected to at least one corresponding column line among the plurality of column lines COLs. The unit comparator 141 may receive a pixel signal from the pixel 111 connected through the corresponding column line COL and receive a lamp signal from the lamp signal generator 160. The unit comparator 141 may output an output signal by comparing the pixel signal and the lamp signal. The counter block 150 may include a plurality of counters 151. Each of the plurality of counters 151 may be connected to the output terminal of each of the unit comparators 141. The counter 151 may count the output signal of the unit comparator 141 according to a counter clock signal CTCS and output it as a digital signal. Meanwhile, the unit comparator 141 and the counter 151 may be a CDS circuit that performs correlated double sampling CDS. Further, the ADC block 130 may include a plurality of ADCs. The ADC may include the unit comparator 141 and the counter 151 connected to each other.

The lamp signal generator 160 may generate the lamp signal RAMP. The lamp signal RAMP may be a reference signal compared to the pixel signal. The lamp signal generator 160 may generate the lamp signal RAMP in response to a lamp control signal CTRP provided from the timing signal generator 170. The lamp control signal CTRP may include at least one of a lamp enable signal and a mode signal. When the lamp enable signal is activated, the lamp signal generator 160 may generate the lamp signal RAMP with a slope according to the mode signal.

The buffer 180 may include a memory block 181 and a sense amplifier 182. The memory block 181 may include a plurality of column memories 183. Each of the plurality of column memories 183 may be connected to the output terminal of one corresponding counter 151. The column memory 183 temporarily stores the digital signal output from the counter 151 and outputs the stored digital signal to the sense amplifier 182. The sense amplifier 182 may amplify the digital signal output from the column memory 183 and output it as image data IDTA. The image data IDTA may include multiple pixel values arranged according to rows and columns. Each pixel value may include a digital signal that is converted from a pixel signal, which is an analog signal.

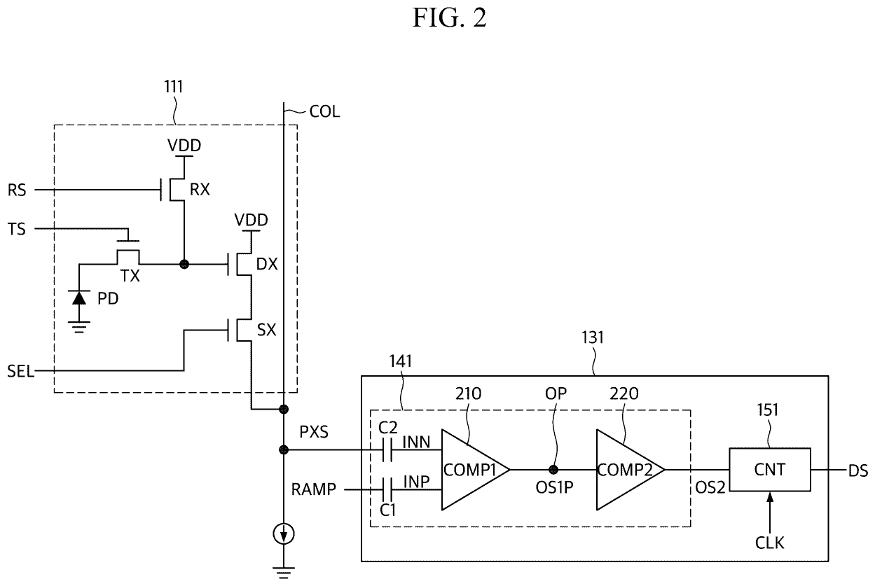

FIG. 2 is a diagram for explaining pixels and an ADC of an image sensor according to an example embodiment.

Referring to FIGS. 1 and 2, the image sensor 100 may include the pixel 111 and an ADC 131. The pixel 111 and the ADC 131 may be connected to each other through the column line COL. The pixel 111 may detect incident light and output a pixel signal PXS. When the pixel signal PXS is input through the column line COL, the ADC 131 may convert the input pixel signal PXS into a digital signal DS and output it.

In a specific example embodiment, the pixel 111 may include photodiode PD, a transmission transistor TX, a reset transistor RX, a driving transistor DX, and a selection transistor SX. The photodiode PD may generate charges depending on the incident light during exposure time. Meanwhile, the number and connection structure of transistors included in the pixel 111 may be modified in various ways.

One end of the reset transistor RX is connected to a power node to which the supply power is applied, and the other end of the reset transistor RX may be connected to a floating diffusion node. The reset controlling signal RS output from the row driver 120 may be input to the gate of the reset transistor RX. The reset transistor RX may change the voltage level of the floating diffusion node to the reset level in response to the reset controlling signal RS. The reset level may be determined by a voltage level VDD of the supply power. The supplied power may be external power supplied from outside, or may be power generated inside the image sensor 100 by an external power source.

One end of the transmission transistor TX may be connected to the photodiode PD, and the other end of the transmission transistor TX may be connected to a floating diffusion node. A transmission controlling signal TS output from the row driver 120 may be input to the gate of the transmission transistor TX. In response to the transmission controlling signal TS, the transmission transistor TX may transmit a signal according to the charge generated by the photodiode PD to the floating diffusion node.

One end of the driving transistor DX may be connected to the power node, and the other end of the driving transistor DX may be connected to one end of the selection transistor SX. The gate of the driving transistor DX may be connected to a floating diffusion node, and the driving transistor DX may transmit a signal to one end of the selection transistor SX in response to the voltage of the floating diffusion node.

One end of the selection transistor SX may be connected to the other end of the driving transistor DX, and the other end of the selection transistor SX may be connected to the column line COL. A row line may be connected to the gate of the selection transistor SX, and a selection signal SEL output from the row driver 120 may be input to the gate of the selection transistor SX. In response to the selection signal SEL, the selection transistor SX may output the signal transmitted from the driving transistor DX as the pixel signal PXS in the column line COL.

The ADC 131 may include the unit comparator 141 and the counter 151. When the pixel signal PXS and the lamp signal RAMP are input, the unit comparator 141 may output an output signal representing the comparison result of the pixel signal PXS and the lamp signal RAMP.

The unit comparator 141 may include at least one comparator. In an example embodiment, the unit comparator 141 may include a first comparator 210 and a second comparator 220. An output node OP of the first comparator 210 may be connected to an input node of the second comparator 220. In an example embodiment, the first comparator 210 may include a differential amplifier. For example, as a differential amplifier, the first comparator 210 may be implemented with an operational transconductance amplifier OTA, an operational amplifier, and so on.

The unit comparator 141 may further include a first capacitor C1 and a second capacitor C2 connected to the input node of the first comparator 210. For example, the unit comparator 141 may include the first capacitor C1 connected to a first input node of the first comparator 210 and the second capacitor C2 connected to a second input node of the first comparator 210.

The lamp signal RAMP may be input as a reference signal INP to the first input node of the first comparator 210 through the first capacitor C1. The lamp signal RAMP may be voltage that increases or decreases linearly. The pixel signal PXS may be input as an input signal INN to the second input node of the first comparator 210 through the second capacitor C2. The first comparator 210 may compare the reference signal INP and the input signal INN in a section of comparison operation, and may output a first output signal OSIP indicating the comparison result through the output node OP. The second comparator 220 may amplify or invert the first output signal OSIP output from the first comparator 210. For example, the second comparator 220 may be implemented with an amplifier and inverter. The second comparator 220 may output a second output signal OS2 corresponding to the first output signal OS1P to the counter 151. Meanwhile, the number and connection structure of comparators may be modified in various ways.

The counter 151 may count the output signal of the unit comparator 141 based on a clock signal CLK and output the digital signal DS. For example, the clock signal CLK may be a signal that repeats between logical values 0 and 1 at a constant cycle. When the logical value of the output signal of the unit comparator 141 is 1 (or 0), the counter 151 may increase the count value according to the period of the clock signal CLK. When the logic value of the output signal changes, the counter 151 may output the final count value as the digital signal DS. The counter 151 may transmit the digital signal DS to the buffer 180.

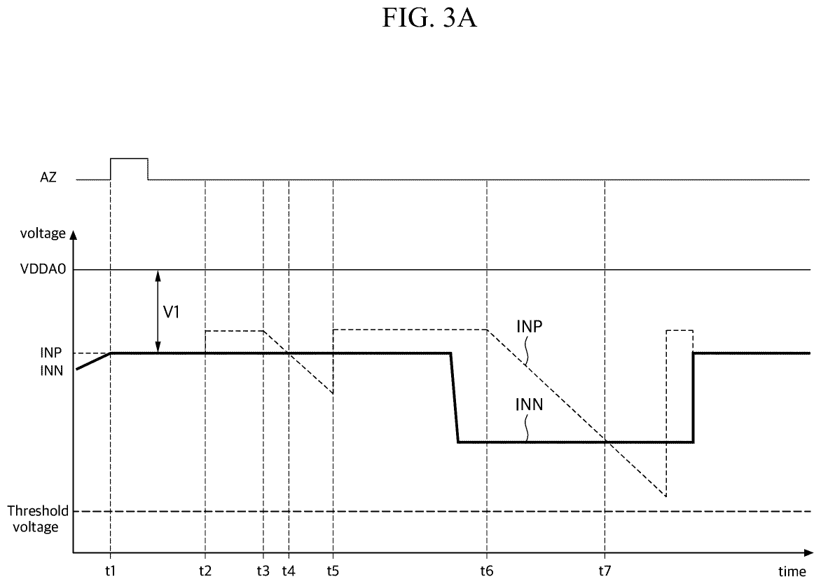

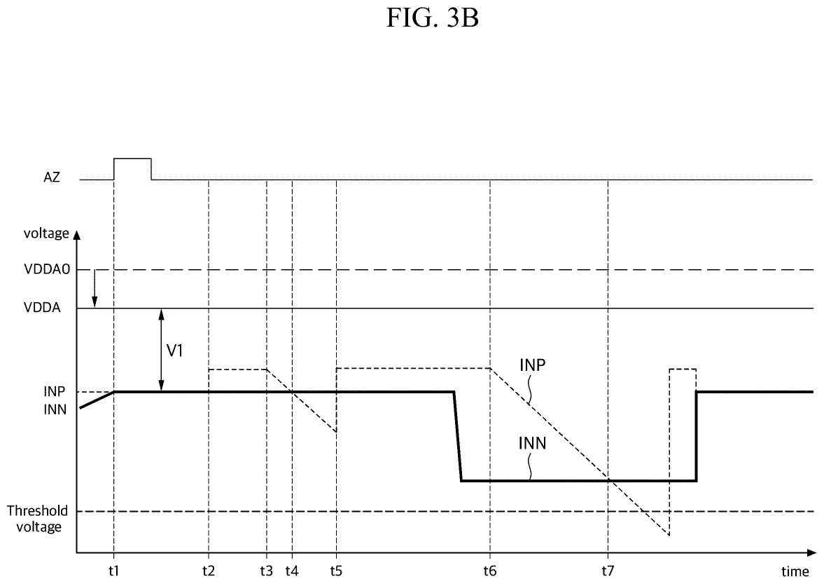

Further, according to an example embodiment, the first comparator 210 may perform an auto-zero operation before the comparison operation. The auto-zero operation may be an operation to initialize (or reset) the voltage levels of the reference signal INP and the input signal INN to remove the offset voltage of the input voltages, the reference signal INP and the input signal INN. According to the auto-zero operation, the voltage levels of the reference signal INP and the input signal INN may be initialized to the auto-zero level. In an example embodiment, the first comparator 210 may further include a switch. The voltage levels of the reference signal INP and the input signal INN may be changed to the auto-zero level by the switch. The auto-zero level may vary depending on the voltage level of the power supply. This will be described in detail with reference to the drawings below. FIGS. 3A and 3B are diagrams for explaining the operation of a comparator according to the power supply according to some example embodiments. FIG. 3B illustrates the waveform of the comparator when the voltage level of the power supply is lower than that of FIG. 3A.

Referring to FIGS. 3A and 3B, the comparator performs an auto-zero operation and may then perform comparison operations. Here, the comparator may be the above described unit comparator 141 or the first comparator 210. The reference signal INP and the input signal INN may be input to the comparator. In addition, the auto-zero operation of the comparator may be implemented by the closing operation of a switch included in the comparator.

The voltage levels of the reference signal INP and the input signal INN input to the comparator may be different from each other due to the offset voltage before a first time point t1.

In an example embodiment, the comparator may perform an auto-zero operation in response to an auto-zero signal AZ at the first time point t1. In this case, the voltage levels of the reference signal INP and the input signal INN may be equal or substantially equal to each other. At this time, the voltage levels of the reference signal INP and the input signal INN may be the auto-zero level. The auto-zero level may be a voltage level that serves as a standard in which the input offset is removed for performing a comparison operation.

The auto-zero level in FIGS. 3A and 3B may be a level obtained by subtracting a first level V1 from the voltage level (or the driving voltage level) VDDAO and VDDA of the power supply. Here, the first level V1 may be the voltage level of a drain-source voltage (a D-S voltage) of the load transistor (for example, a P-type metal oxide semiconductor field effect transistor (MOSFET)) included in the comparator. Here, one end (for example, the source) of the load transistor may be connected to a power node to which the supply power is applied, and the other end (for example, the drain) of the load transistor may be connected to the output node. The gate of the load transistor may be connected to the other terminal (or an output node) of the load transistor. In other words, the load transistor may be a diode connected transistor. The diode connection may indicate a structure in which the gate of the transistor and the drain (or the source) of the transistor are connected. In this case, the drain-source voltage (the D-S voltage) of the load transistor may be equal or substantially equal to a gate-source voltage (a G-S voltage). In other words, the first level V1 may be the voltage level of the G-S voltage of the load transistor.

The comparator may perform a comparison operation at a second time point t2 after the auto-zero operation is performed.

Specifically, an offset level may be applied to the voltage level of the reference signal INP at the second time point t2. In other words, at the second time point t2, the voltage level of the reference signal INP may increase. During a certain period of time from a third time point t3 to a fifth time point t5, the voltage level of the reference signal INP may fall along a certain slope. For example, for a certain period of time, the lamp signal RAMP may be input to the comparator as the reference signal INP. The length of a certain period of time may be set in advance. After the fifth time point t5, the voltage level of the reference signal INP may increase, and may become the same as the voltage level before the third time point t3. In other words, the voltage level of the reference signal INP after the fifth time point t5 may be what is obtained by an offset level being applied to the auto-zero level. Meanwhile, the counter connected to the comparator may identify the time point at which the voltage level of the reference signal INP and the voltage level of the input signal INN become the same through the output signal of the comparator. The counter may obtain the first count value corresponding to the time from the third time point t3 to a fourth time point t4 by counting using a clock signal during the time from the third time point t3 when the voltage level of the reference signal INP begins to fall to the fourth time point t4 when the voltage level of the reference signal INP and the voltage level of the input signal INN become the same.

Then, the pixel signal PXS may be input to the comparator as the input signal INN. In this case, the voltage level of the input signal INN may vary depending on the voltage level of the pixel signal PXS. For a certain period of time from a sixth time point t6, the voltage level of the reference signal INP may decrease along a certain slope. For example, for a certain period of time, the lamp signal RAMP may be input to the comparator as the reference signal INP. The length of the certain period of time may be preset. The counter may count using a clock signal during the time from the sixth time point t6 when the voltage level of the reference signal INP begins to fall to a seventh time point t7 when the voltage level of the reference signal INP and the voltage level of the input signal INN become the same to obtain a second count value corresponding to the time from the sixth time point t6 to the seventh time point t7. The counter may obtain the difference between the second count value and the first count value as a digital signal corresponding to the pixel signal.

Since the offset of each pixel is different for each frame, the offset needs to be removed for each pixel so that the comparator and counter may accurately measure the actual signal.

Here, the first count value is a reference reset value, and the second count value may be a signal value, which is an actual signal value, and the counter may calculate the difference between the signal value and the reset value to remove the offset for each pixel.

Further, the second driving voltage level VDDA in FIG. 3B is a value smaller than the first driving voltage level VDDAO. For example, the first driving voltage level VDDAO may be 2.8 V to 3.8 V, and the second driving voltage level VDDA may be 1.1 V to 2.2 V. However, it is only a mere example embodiment, and the specific values of the first driving voltage level VDDAO and the second driving voltage level VDDA may vary. The auto-zero level may be a value obtained by subtracting the first level V1 from the second driving voltage level VDDA of power supply. In this case, there may be a time section in which the voltage level of the reference signal INP or the input signal INN falls outside the range within which the comparator can operate normally. For example, as illustrated in FIG. 3B, a time section may occur in which the reference signal INP is lower than the threshold voltage. In this case, the comparator may not be able to perform comparison operations properly, such as the transistor in the comparator behaving erratically before being turned off.

The range of input signals that the image sensor provides to the comparator may be set to match the specifications of the pixels. In order to set the range of input signals so that the comparator may operate within the normal operating voltage of the comparator, it is necessary to supply an appropriate driving power to the comparator, and there is a problem that the power consumption increases as the voltage value of the driving power increases. Therefore, a method for effectively comparing the same range of input signals while lowering the voltage level of the driving power is required, and a method for increasing the auto-zero level of the comparator may be considered as a solution to this.

According to an example embodiment, provided is a comparator that operates normally by lowering the voltage level of power supply while increasing the auto-zero level, and an image sensor including the comparator. In other words, according to an example embodiment, the comparator may secure a sufficient input range while being driven at low voltage.

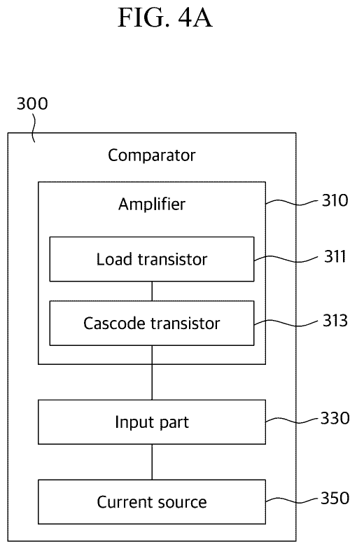

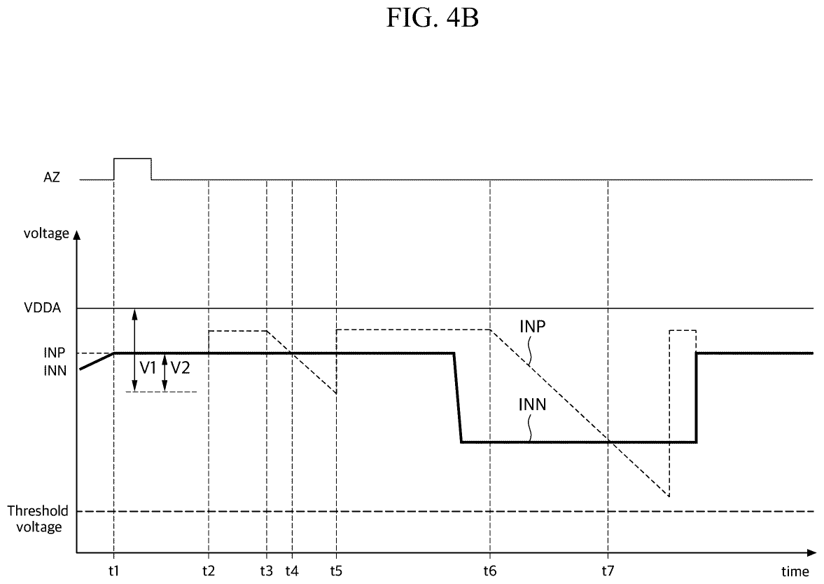

FIG. 4A is a diagram for explaining a comparator according to an example embodiment.

Referring to FIG. 4A, a comparator 300 according to an example embodiment may include an amplifier 310, an input part 330 and a common current source 350.

In an example embodiment, the amplifier 310 may include a load transistor 311 and a cascode transistor 313. The amplifier 310 may output an output signal based on the difference between a reference signal INP and an input signal INN input to the input part 330 through an output node. Here, the output signal may represent a signal in which the difference between the input signal INN and the reference signal INP is amplified by the load transistor 311.

In an example embodiment, the load transistor 311 may include a first load transistor and a second load transistor. The amplifier 310 may output a first output signal and a second output signal based on the difference between the reference signal INP and the input signal INN input to the input part 330 through a first output node and a second output node, respectively.

The supply power may be applied to the amplifier 310. The amplifier 310 may be connected to a power node to which the supply power is applied. The amplifier 310 may be connected to the input part 330. For example, the power supply may be connected and supplied to one end of the load transistor 311, and the input part 330 may be connected to the other end, so that a signal that amplifies the difference between the reference signal INP and the input signal INN may be output through the first output node and the second output node connected to the other end of the load transistor.

The cascode transistor 313 may be connected to the input part 330 and the load transistor 311, and may increase the auto-zero level in the auto-zero section where the voltage levels of the reference signal INP and the input signal INN of the input part 330 are initialized. For example, the cascode transistor 313 may be connected to one end of the first input transistor of the input part 330 and one end of the first load transistor to increase the auto-zero level. The auto-zero period may be a time period (or time section) in which an auto-zero operation that initializes the voltage levels of the reference signal INP and the input signal INN is performed.

The reference signal INP and the input signal INN may be input to the input part 330. In an example embodiment, the input part 330 may include a first input transistor and a second input transistor. In an example embodiment, the input part 330 may further include a first capacitor connected to the gate of the first input transistor. In an example embodiment, the first capacitor may transmit a ramp signal RAMP as a reference signal INP to the gate of the first input transistor.

In an example embodiment, the first input transistor and the second input transistor may be the same type of MOSFETs. Here, the type may be either the first type or the second type. For example, the first type may be one of the P-type and the N-type, and the second type may be the remaining one between the two types, which are the P-type and the N-type.

In an example embodiment, the input part 330 may further include a second capacitor connected to the gate of the second input transistor. In an example embodiment, the second capacitor may transmit a pixel signal PXS as the input signal INN to the gate of the second input transistor.

In an example embodiment, the input part 330 may be connected to one end of the amplifier 310. In another example embodiment, the input part 330 may be connected to the second output node of the amplifier 310.

The common current source 350 may supply bias current to the input part 330. For example, the bias current may be a constant current with a constant current level. The common current source 350 may be commonly connected to the first input transistor and the second input transistor. In an example embodiment, the sum of the current levels of the current flowing in the first transistor and the current flowing in the second transistor may be equal or substantially equal to the current level of the bias current. In other words, the bias current may flow dividedly to the first input transistor and the second input transistor. For example, the current flowing in the first input transistor may have a larger current level as the value obtained by subtracting the input signal INN input to the gate of the second input transistor from the reference signal INP input to the gate of the first input transistor increases. In addition, the current flowing in the second input transistor may have a larger current level as the value obtained by subtracting the reference signal INP input to the gate of the first input transistor from the input signal INN input to the gate of the second input transistor increases.

The bias currents supplied by the common current source 350 to the first input transistor and the second input transistor, respectively, are determined by the difference between the input signal INN and the reference signal INP, and may be amplified by the load transistor 311 of the amplifier 310 to output output signals to the first output node and the second output node, respectively.

In an example embodiment, during the auto-zero period, the current level of the current flowing in the first input transistor and the current level of the current flowing in the second input transistor may be the same or substantially the same.

In an example embodiment, the common current source 350 may include a device that operates as a current source. In an example embodiment, the common current source 350 may include a transistor that operates as a current source. For example, the transistor may be a MOSFET operating in the saturation region as a tail current source. When the gate-source voltage (the G-S voltage) has a voltage level greater than the threshold voltage, and the drain-source voltage (the D-S voltage) has a voltage level above a certain level, MOSFETs may operate in the saturation region.

According to an example embodiment of the present disclosure, the amplifier 310 may include a first load transistor and a first cascode transistor. The first load transistor and the first cascode transistor may be connected to each other. The first output node may be connected between the first load transistor and the first cascode transistor. The first load transistor may be a transistor to control the voltage so that a constant current flows in the amplifier 310 during the auto-zero period. The first cascode transistor may be a transistor to increase the auto-zero level.

In an example embodiment, the first load transistor and the first cascade transistor may be the same type of MOSFETs. In an example embodiment, when the first load transistor and the first cascade transistor are P-type MOSFETs, the source of the first cascade transistor is connected to the drain of the first load transistor to block the gate of the first load transistor and the drain of the first load transistor from being connected to each other. In other words, the first cascade transistor may be connected to the first load transistor so that the first load transistor is structured to prevent diode connection.

In an example embodiment, the first load transistor and the first cascade transistor may be the first type MOSFETs, and the first input transistor and the second input transistor may be the second type MOSFETs. For example, the first type may be P-type, and the second type may be the N-type. However, it is only a mere example embodiment, and the first type may be transformed into the N-type, and the second type may be transformed into the P-type.

In an example embodiment, the amplifier 310 may include a second load transistor. The second load transistor may correspond to the first load transistor. For example, the second load transistor may be the same type of MOSFET as the first load transistor. One end of the first load transistor may be connected to a power node to which the supply power is applied, and one end of the second load transistor may be connected to a power node to which the supply power is applied. The gate of the first load transistor and the gate of the second load transistor may be connected to each other.

FIG. 4B is a diagram for explaining the operation of a comparator according to an example embodiment.

Referring to FIGS. 4A and 4B, the comparator 300 may operate the auto-zero operation before performing the comparison operation. For example, the auto-zero operation may be performed during a time interval in which the auto-zero signal AZ is in the first state (for example, a high state), and then the comparison operation may be performed. Meanwhile, description of the comparison operation after the second time point t2 is omitted because it overlaps with the description of FIGS. 3A and 3B.

The comparator 300 may perform an auto-zero operation to equalize or substantially equalize the voltage levels of the reference signal INP and the input signal INN. Here, the voltage level may be an auto-zero level. The second driving voltage level VDDA of the power supply in FIG. 4B is smaller than the first driving voltage level VDDAO in FIG. 3A, and the auto-zero level in FIG. 4B is greater than the auto-zero level in FIG. 3B. Referring to FIG. 4B, the voltage levels of the reference signal INP and the input signal INN may be maintained to be greater than a predetermined reference level (for example, threshold voltage) while the comparator 300 performs the comparison operation. In other words, the comparator 300 may normally perform the comparison operation using the low-voltage power supply.

In a specific example embodiment, referring to FIG. 4B, the auto-zero level may be a voltage level obtained by subtracting the difference between the first level V1 and a second level V2 from the second driving voltage level VDDA of the power supply. In other words, the auto-zero level may be a voltage level obtained by subtracting the first level V1 from the second driving voltage level VDDA of the power supply and adding the second level V2. In an example embodiment, the first level V1 may be the voltage level of the gate-source voltage (the G-S voltage) of the first load transistor (for example, the P-type MOSFET) of the amplifier 310. The second level V2 may be the voltage level of the threshold voltage of the first load transistor (for example, the P-type MOSFET) of the amplifier 310. The difference between the first level V1 and the second level V2 may be the voltage level of the drain-source voltage (the D-S voltage) of the first load transistor (for example, the P-type MOSFET) of the amplifier 310. For example, the first load transistor may operate in the saturation region. In this case, the voltage level of the D-S voltage may be the difference between the voltage levels of the G-S voltage and the threshold voltage.

According to an example embodiment, since the first cascade transistor is connected to the first load transistor, the diode connection of the first load transistor may be blocked. In other words, due to the addition of the first cascade transistor, the gate of the first load transistor may not be connected to the source of the first load transistor. According to this structural connection, the auto-zero level of FIG. 4B may cause a technical effect that is higher than the auto-zero level of FIG. 3B. According to an example embodiment, since the comparator 300 includes a first cascode transistor, it may normally perform comparison operation at a relatively low voltage, and may secure a sufficient input range accordingly.

In an example embodiment, the comparator 300 may include a first switch and a second switch. The first switch may switch the connection between the gate of the first input transistor and the first output node, and the second switch may switch the connection between the gate of the second input transistor and the second output node. In an example embodiment, the first switch and the second switch may be implemented in the form of transistors.

During the auto-zero period, in response to the auto-zero signal AZ having a first state, the first switch may connect the gate of the first input transistor and the first output node, and in response to the auto-zero signal AZ with the first state, the second switch may connect the gate of the second input transistor and the second output node. Here, the first state may be a high state in which the signal level is higher than the reference value. In this case, the voltage levels of the gate of the first input transistor, the first output node, the gate of the second input transistor, and the second output node may be the same. The voltage level at this time may be an auto-zero level. Further, the first switch may block the connection of the gate of the first input transistor and the first output node in response to the auto-zero signal AZ of the second state, and the second switch may block the connection of the gate of the second input transistor and the second output node in response to the auto-zero signal AZ of the second state. Here, the second state may be a low state in which the signal level is lower than the reference value.

Hereinafter, specific example embodiments of the comparator 300 of the present disclosure will be described.

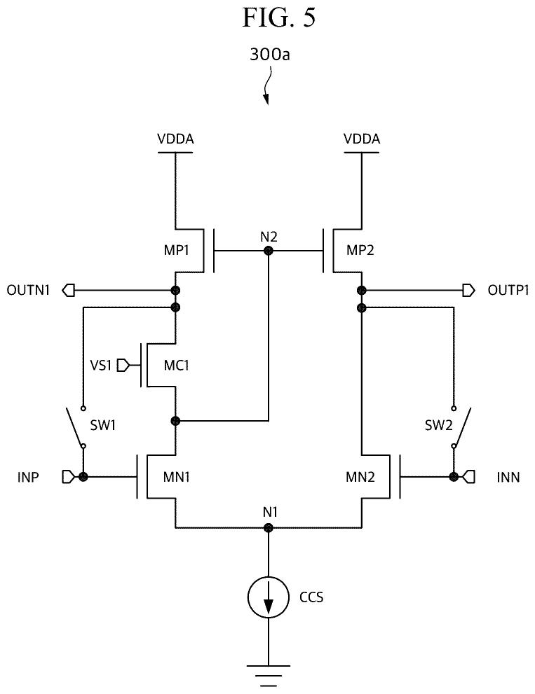

FIG. 5 is a circuit diagram illustrating a comparator according to an example embodiment.

Referring to FIG. 5, the comparator 300a may include a current source CCS connected to a first input transistor MN1, a second input transistor MN2, a first load transistor MP1, a second load transistor MP2, the first cascade transistor MC1, and a first node N1. Each transistor may include a gate, one end, and the other end. The one end may be either a source or a drain, and the other end may be the remaining one of the two.

In an example embodiment, the first load transistor MP1, the second load transistor MP2, and the first cascade transistor MC1 may be first type MOSFETs, and the first input transistor MN1 and the second input transistor MN2 may be the second type MOSFETs. For example, the first type may be the P-type, and the second type may be the N-type. Hereinafter, example embodiments will be described based thereon. Meanwhile, the above example embodiments are mere example embodiments, and thus the first type and the second type may be modified to be opposite to each other. Any description that overlaps with the above descriptions will be omitted.

Referring to FIGS. 4A and 5, the comparator 300 and the comparator 300a may include the amplifier 310, the input part 330 and the common current source 350. In the comparator 300 and the comparator 300a of a series connection structure, one end of the input part 330 may be connected to one end of the amplifier 310, and the other end of the input part 340 may be connected to one end of the common current source 350.

The amplifier 310 may include the first load transistor MP1 connected between the power node and the first output node, the second load transistor MP2 connected between the power node and the second output node, and the first cascode transistor MC1 connected between the first output node and the first input transistor MN1.

The input part 330 may include the first input transistor MN1 connected between the first cascode transistor MC1 and the first node N1. The input part 330 may include the second input transistor MN2 connected between the second output node and the first node N1. The common current source 350 may include the current source CCS connected to the first node N1.

In a specific example embodiment, the current source CCS may be connected to the first node N1. The first node N1 may be commonly connected to the first input transistor MN1 and the second input transistor MN2, and may be referred to as a common node. The current source CCS may provide bias current. The current level of the bias current may be equal or substantially equal to the sum of the current levels of the currents flowing through each of the first input transistor MN1 and the second input transistor MN2.

The gate of the first input transistor MN1 may be connected to the first input node where the reference signal INP is input. One end (for example, the drain) of the first input transistor MN1 may be connected to the other end (for example, the drain) of the first cascade transistor MC1, and the other end (for example, the source) of the first input transistor MN1 may be connected to the first node N1.

One end (for example, the source) of the first load transistor MP1 may be connected to a power node to which the supply power with a voltage level VDDA is applied. The other end (for example, the drain) of the first load transistor MP1 may be connected to the first output node. The first output node may output a first output signal OUTNI, which is a signal that amplifies the difference between the reference signal INP and the input signal INN. One end (for example, the source) of the second load transistor MP2 may be connected to a power node to which the supply power with the second driving voltage level VDDA is applied. The other end (for example, the drain) of the second load transistor MP2 may be connected to the second output node. The second output node may output a second output signal OUTP1, which is a signal that amplifies the difference between the reference signal INP and the input signal INN.

In an example embodiment, the gates of the first load transistor MP1 and the second load transistor MP2 may be connected to each other.

A control signal VS1 may be input to the gate of the first cascade transistor MC1. The control signal VS1 may be a bias voltage applied from an external source (for example, the timing signal generator 170, and so on). The bias voltage may be a constant voltage with a constant voltage level. In this case, the first cascade transistor MC1 may operate in the saturation region. In the saturation region, current may flow stably through the channel of the first cascade transistor MC1. Alternatively, the first cascade transistor MC1 may operate in the linear region.

In an example embodiment, one end (for example, the source) of the first cascade transistor MC1 may be connected to the first output node, and the other end (for example, the drain) of the first cascade transistor MC1 may be connected to a second node N2. The second node N2 may be connected to the gate of the first load transistor MP1. In this case, the first cascade transistor MC1 may block the gate of the first load transistor MP1 from being connected to the drain of the first load transistor MP1. In other words, as the diode connection of the first load transistor MP1 is blocked due to the first cascade transistor MC1, the auto-zero level may rise.

According to an example embodiment, the comparator 300a may further include a first switch SW1 and a second switch SW2. In an example embodiment, each of the first switch SW1 and the second switch SW2 may be implemented as a MOSFET that switches to turn on or off depending on an auto-zero signal.

The first switch SW1 may switch the connection between the first input node and the first output node, and the second switch SW2 may switch the connection between the second input node and the second output node. For example, during the auto-zero period, the first switch SW1 may connect the first input node and the first output node to each other, and the second switch SW2 may connect the second input node and second output node to each other. In this case, the voltage levels of the first input node, the first output node, second input node, and second output node may be initialized (or reset) to an auto-zero level. Further, during the auto-zero period, the current level of the current flowing through the first input transistor MN1 may be the same as the current level of the current flowing through the second input transistor MN2. After then, in order to operate the comparison operation, the first switch SW1 may open the first input node and the first output node to each other, and the second switch SW2 may open the second input node and second output node to each other.

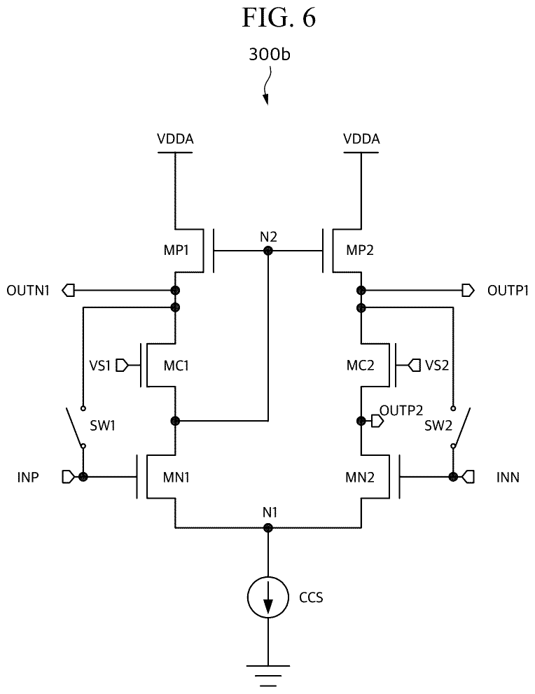

FIG. 6 is a circuit diagram illustrating a comparator according to an example embodiment.

Referring to FIG. 6, a comparator 300b may include the current source CCS connected to the first input transistor MN1, the second input transistor MN2, the first load transistor MP1, the second load transistor MP2, the first cascade transistor MC1, a second cascade transistor MC2, and the first node N1.

In an example embodiment, the first load transistor MP1, the second load transistor MP2, the first cascade transistor MC1, and the second cascade transistor MC2 may be the first type MOSFETs, and the first input transistor MN1 and the second input transistor MN2 may be the second type MOSFETs. For example, the first type may be the P-type, and the second type may be the N-type. Hereinafter, example embodiments will be described based thereon. However, the example embodiments are mere example embodiments, and thus the first type and the second type may be modified to be opposite to each other. Any description that overlaps with the above descriptions will be omitted.

Referring to FIGS. 4A and 6, the comparator 300 and the comparator 300b may include the amplifier 310, the input part 330, and the common current source 350. In the comparator 300 and the comparator 300b of a series connection structure, one end of the input part 330 may be connected to one end of the amplifier 310, and the other end of the input part 330 may be connected to one end of the common current source 350.

The amplifier 310 may include the first load transistor MP1 connected between the power node and the first output node, the second load transistor MP2 connected between the power node and the second output node, the first cascode transistor MC1 connected between the first output node and the first input transistor MN1, and the second cascode transistor MC2 connected between the second output node and the second input transistor MN2.

The input part 330 may include the first input transistor MN1 connected between the first cascode transistor MC1 and the first node N1. The input part 330 may include the second input transistor MN2 connected between the second output node and the first node N1. The common current source 350 may include the current source CCS connected to the first node N1. The first node N1 may be referred to as a common node.

In an example embodiment, one end (for example, the source) of the second cascade transistor MC2 may be connected to the second output node, and the other end (for example, the drain) of the second cascade transistor MC2 may be connected to the third output node. The control signal VS1 may be input to the gate of the second cascade transistor MC2. The control signal VS1 may be a bias voltage applied externally. In this case, the second cascade transistor MC2 may operate in the saturation or linear region. In an example embodiment, the control signal VS1 or a control signal such as VS2 may be input to the gates of the second cascode transistor MC2 and the first cascode transistor MC1.

In order for the comparator 300 to operate normally, it is necessary for all transistors included in the comparator 300 to operate in a saturated state. In a structure where the second node N2, to which both the gates of the first load transistor MP1 and the second load transistor MP2 are connected, is connected to one end of the first input transistor MP1, it may be difficult to design an appropriate bias voltage for each transistor because the specifications of the transistors may vary depending on the process variation of each transistor.

According to an example embodiment, a folded structure is applied to the comparator so that an appropriate bias voltage may be input to the load transistor and the cascode transistor, and additional voltage headroom over the input signal range can be secured.

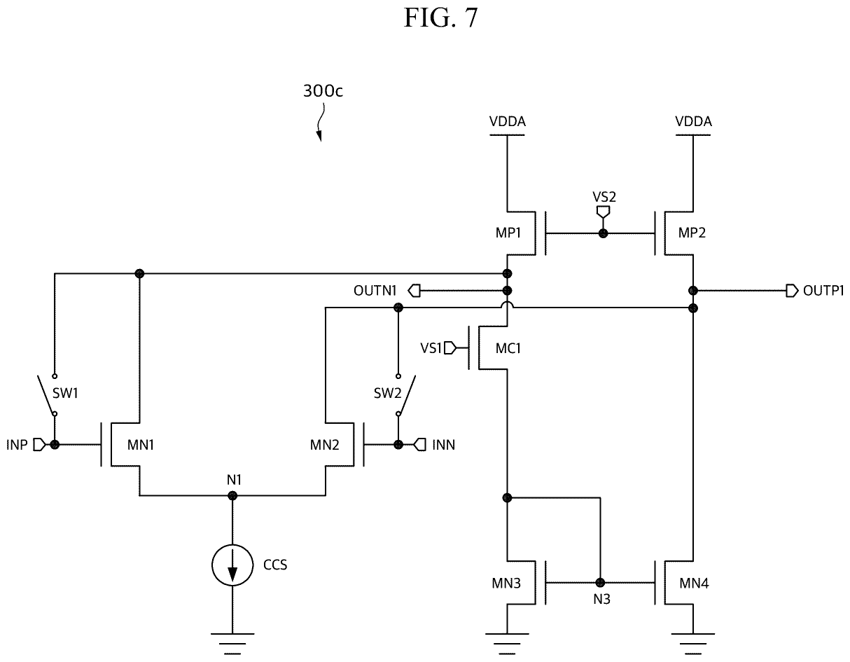

FIG. 7 is a circuit diagram illustrating a comparator according to an example embodiment.

Referring to FIG. 7, a comparator 300c may include the current source CCS connected to the first input transistor MN1, the second input transistor MN2, the first load transistor MP1, the second load transistor MP2, a third load transistor MN3, a fourth load transistor MN4, the first cascade transistor MC1 and the first node N1.

In an example embodiment, the first load transistor MP1, the second load transistor MP2, and the first cascade transistor MC1 may be the first type MOSFETs, and the first input transistor MN1, the second input transistor MN2, the third load transistor MN3, and the fourth load transistor MN4 may be the second type MOSFETs. For example, the first type may be the P-type, and the second type may be the N-type. Hereinafter, example embodiments are described based thereon. Further, the first type and the second type may be modified to be opposite to each other. Descriptions that overlaps with the above descriptions will be omitted.

Referring to FIGS. 4A and 7, the comparator 300 and the comparator 300c may include the amplifier 310, the input part 330, and the common current source 350. In the comparator 300 and the comparator 300c of a folded connection structure, the first input transistor MN1 of the input part 330 may be connected to the first output node of the amplifier 310, and the second input transistor MN2 of the input part 330 may be connected to the second output node of the amplifier 310.

The amplifier 310 may include the first load transistor MP1 connected between a power node and the first output node, the first cascode transistor MC1 connected to the first output node, and the third load transistor MN3 connected to the first cascode transistor MC1.

Further, the amplifier 310 may include the second load transistor MP2 connected between the power node and second output node, and the fourth load transistor MN4 connected to second output node.

The input part 330 may include the first input transistor MN1 connected between the first output node and the first node N1. The input part 330 may include the second input transistor MN2 connected between the second output node and the first node N1. The common current source 350 may include the current source CCS connected to the first node N1. The first node N1 may be referred to as a common node.

In a specific example embodiment, gates of the first load transistor MP1 and the second load transistor MP2 may be connected to each other. For example, a control signal VS2 may be input to the gates of the first load transistor MP1 and the second load transistor MP2. The control signal VS2 may be a bias voltage applied from an external source (for example, the timing signal generator 170, etc.). In this case, the first load transistor MP1 and the second load transistor MP2 may operate in the saturation region. Accordingly, the current of each of the first load transistor MP1 and the second load transistor MP2 may flow stably.

One end (for example, the drain) of the third load transistor MN3 may be connected to the other end (for example, the drain) of the first cascade transistor MC1. In an example embodiment, the other end (for example, the source) of the third load transistor MN3 may be grounded.

One end (for example, the drain) of the fourth load transistor MN4 may be connected to the second output node. The second output node may be connected to the other end (for example, the drain) of the second load transistor MP2. In an example embodiment, the other end (for example, the source) of the fourth load transistor MN4 may be grounded.

In an example embodiment, the gate of the third load transistor MN3 may be connected to the gate of the fourth load transistor MN4.

In an example embodiment, gates of the third load transistor MN3 and the fourth load transistor MN4 may be connected to a third node N3. The third node N3 may be connected to the other end (for example, the drain) of the first cascade transistor MC1 and one end (for example, the drain) of the third load transistor MN3. In this case, the gate of the third load transistor MN3 may be connected to the drain of the third load transistor MN3, and thus the third load transistor MN3 may have a diode connection structure. In this case, the third load transistor MN3 may operate in the saturation region. Meanwhile, even in this case, since the gate of the first load transistor MP1 is not connected to the drain, the diode connection of the first load transistor MP1 may be blocked. As a result, the auto-zero level may be a voltage level obtained by subtracting the difference between the first level V1 and the second level V2 from the second driving voltage level VDDA of the power supply, as illustrated in FIG. 4B. In an example embodiment, the first level V1 may be the voltage level of the G-S voltage of the first load transistor MP1, and the second level V2 may be the voltage level of the threshold voltage of the first load transistor MP1.

The current flowing in the third load transistor MN3 may be the same or substantially the same as the current flowing in the fourth load transistor MN4. That is, the third load transistor MN3 and the fourth load transistor MN4 may form a current mirror circuit.

In an example embodiment, the current level of the current flowing through the first input transistor MN1 in the auto-zero period may be the same or substantially the same as the current level of the current flowing through the second input transistor MN2.

In an example embodiment, the comparator 300c may further include the first switch SW1 and the second switch SW2. In an example embodiment, each of the first switch SW1 and the second switch SW2 may be implemented as a MOSFET that switches to turn on or off according to an auto-zero signal. In the auto-zero period, the first switch SW1 may connect the first input node and the first output node to each other, and the second switch SW2 may connect the second input node and second output node to each other.

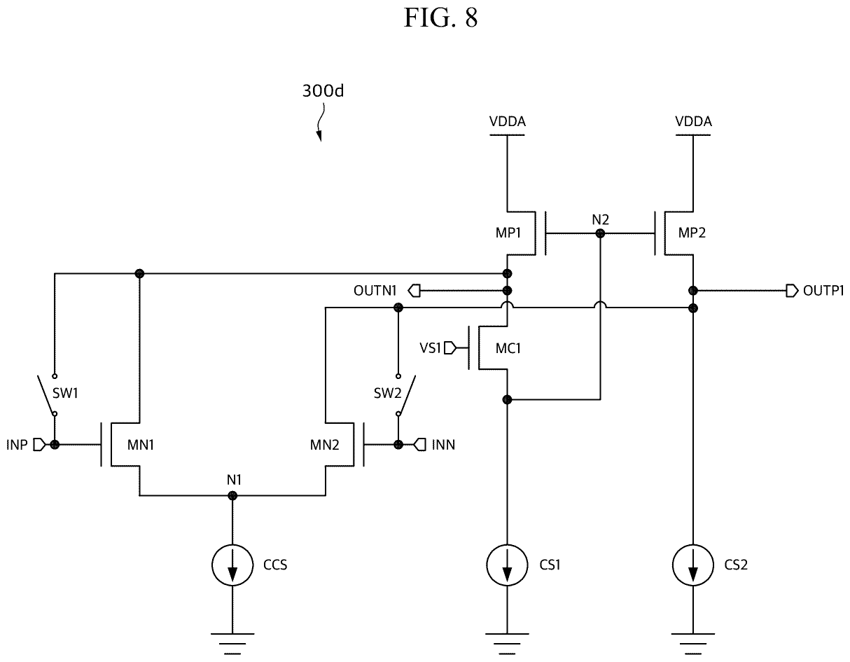

FIG. 8 is a circuit diagram illustrating a comparator according to an example embodiment.

Referring to FIG. 8, a comparator 300d may include the current source CCS connected to the first input transistor MN1, the second input transistor MN2, the first load transistor MP1, the second load transistor MP2, the first cascade transistor MC1 and the first node N1, a first current source CS1 and a second current source CS2.

In an example embodiment, the first load transistor MP1, the second load transistor MP2, and the first cascade transistor MC1 may be the first type MOSFETs, and the first input transistor MN1 and the second input transistor MN2 may be the second type MOSFETs. For example, the first type may be the P-type, and the second type may be the N-type. Hereinafter, example embodiments will be described based thereon. However, the above example embodiments are mere example embodiments, and the first type and the second type may be modified to be opposite to each other. Any description that overlaps with the above descriptions will be omitted.

Referring to FIGS. 4A and 8, the comparator 300 and the comparator 300d may include the amplifier 310, the input part 330, and the common current source 350. In the comparator 300 and the comparator 300d of a folded connection structure, the first input transistor MN1 of the input part 330 may be connected to the first output node of the amplifier 310, and the second input transistor MN2 of the input part 330 may be connected to the second output node of the amplifier 310.

The amplifier 310 may include the first load transistor MP1 connected between a power node and the first output node, the first cascode transistor MC1 connected to the first output node, and the first current source CS1 connected to the first cascode transistor MC1.

Further, the amplifier 310 may include the second load transistor MP2 connected between the power node and second output node, and the second current source CS2 connected to second output node.

The input part 330 may include the first input transistor MN1 connected between the first output node and the first node N1. The input part 330 may also include the second input transistor MN2 connected between the second output node and the first node N1. The common current source 350 may include the current source CCS connected to the first node N1. The first node N1 may be referred to as a common node.

In an example embodiment, one end (for example, the source) of the first cascade transistor MC1 may be connected to the first output node, and the other end (for example, the drain) of the first cascade transistor MC1 may be connected to the second node N2 connected to the gate of the first load transistor MP1. The control signal VS1 may be applied to the gate of the first cascade transistor MC1. The control signal VS1 may be a bias voltage.

In an example embodiment, the first current source CS1 may be connected to the other end (for example, the drain) of the first cascade transistor MC1. The second current source CS2 may be connected to the other end (for example, the drain) of the second load transistor MP2. The first current source CS1 and the second current source CS2 may supply bias current.

The current source CCS may be connected to a common node. In an example embodiment, in the auto-zero period, the current level of the bias current of the first current source CS1 may be the same as the current level of the bias current of the second current source CS2.

The example embodiments may be represented by functional block elements and various processing steps. The above-described example embodiments are merely examples, and other embodiments may be implemented within the scope of the claims to be described later.

In various example embodiments herein, reference may have been made to various circuit elements, including but not limited to capacitors, resistor, inductors, switches, amplifiers, comparators, filters, and transistors. Various different types of digital, analog, active and/or passive components are available for use in implementing the example embodiments. For example, as discussed above, pseudo-resistors can be substituted for passive resistors. Additionally various different transistor types can be used depending on the implementation, whether positive or negative logic is used, manufacturing processes employed, or the like. Furthermore, unless specifically stated otherwise herein, there are many available types of filters, comparators, switches, and the like that can be used to implement the example embodiments.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination of two or more of A, B, and C. Likewise, A and/or B means A, B, or A and B.

When either of the terms “about” or “substantially” is used in this specification in connection with a numerical value, it is intended that the associated numerical value includes a manufacturing or operational tolerance (e.g., ±10%) around the stated numerical value.

Any functional blocks shown in the figures and described above may be implemented in processing circuitry such as hardware including logic circuits, a hardware/software combination such as a processor executing software, or a combination thereof. For example, processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The above-described example embodiments are merely examples, and other embodiments may be implemented within the scope of the claims to be described later.

What is claimed is:

1. A comparator of an image sensor, the comparator comprising:
a first input transistor configured to receive a reference signal;
a second input transistor configured to receive an input signal;
a first load transistor configured to output a first output signal to a first output node based on a difference between the reference signal and the input signal; and
a first cascode transistor coupled to the first input transistor and the first output node.

2. The comparator of claim 1, further comprising a second load transistor, the second transistor including a gate to which a gate of the first load transistor is coupled, one end coupled to supply power, and another end is configured to output a second output signal to a second output node based on the difference between the reference signal and the input signal.

3. The comparator of claim 2, wherein one end of the first cascode transistor is coupled to the first output node, and another end of the first cascode transistor is coupled to a node coupled to the gate of the first load transistor and one end of the first input transistor.

4. The comparator of claim 3, further comprising a common current source, the common current source being configured to supply bias current to the first input transistor and the second input transistor, wherein
the first input transistor is coupled between the first cascode transistor and a common node coupled to the common current source, and
the second input transistor is coupled between the common node and the second output node.

5. The comparator of claim 4, further comprising:
a first switch configured to couple a gate of the first input transistor to the first output node during a predetermined time period; and
a second switch configured to couple a gate of the second input transistor to the second output node during the predetermined time period.

6. The comparator of claim 5, wherein the input signal and the reference signal have a voltage level increased by a threshold voltage of the first cascode transistor during the predetermined time period.

7. The comparator of claim 4, further comprising a second cascode transistor, the second cascode transistor including one end is coupled to the second output node, and another end is coupled to the second input transistor and a third output node configured to output a third signal based on the difference between the reference signal and the input signal.

8. The comparator of claim 2, further comprising a common current source, the common current source being configured to supply bias current to the first input transistor and the second input transistor, wherein
the first input transistor is coupled between the first output node and a common node coupled to the common current source,
the second input transistor is coupled between the common node and the second output node, and
the first cascode transistor is coupled to one end of the first input transistor and the first output node.

9. The comparator of claim 8, further comprising:
a first switch configured to couple a gate of the first input transistor to the first output node during a predetermined time period; and
a second switch configured to couple a gate of the second input transistor to the second output node during the predetermined time period.

10. The comparator of claim 8, further comprising a third load transistor and a fourth load transistor, wherein
a gate of the third load transistor and one end of the third load transistor are coupled to another end of the first cascode transistor, and
a gate of the fourth load transistor is coupled to the gate of the third load transistor and one end of the fourth load transistor is coupled to another end of the second cascode transistor.

11. The comparator of claim 10, wherein the first load transistor, the second load transistor and the first cascode transistor are first type metal oxide semiconductor field effect transistors (MOSFETs), and
the first input transistor, the second input transistor, the third load transistor and the fourth load transistor are second type MOSFETs which are different from the first type MOSFETs.

12. The comparator of claim 8, further comprising:
a first current source coupled to another end of the first cascode transistor; and
a second current source coupled to another end of the second load transistor.

13. An image sensor comprising:
a pixel configured to output a pixel signal;
a lamp generator configured to output a lamp signal; and
a comparator configured to, based on an input signal corresponding to the pixel signal and a reference signal corresponding to the lamp signal, output a first output signal, wherein the comparator comprises:
a first input transistor configured to receive a reference signal;
a second input transistor configured to receive an input signal;
a first load transistor configured to output a first output signal to a first output node based on a difference between the reference signal and the input signal; and
a first cascode transistor coupled to the first input transistor and the first output node.

14. The image sensor of claim 13, wherein the comparator further comprises a second load transistor, the second transistor including a gate to which a gate of the first load transistor is coupled, one end coupled to supply power, and another end is configured to output a second output signal to a second output node based on the difference between the reference signal and the input signal.

15. The image sensor of claim 14, wherein one end of the first cascode transistor is coupled to the first output node, and another end of the first cascode transistor is coupled to a node coupled to the gate of the first load transistor and one end of the first input transistor.

16. The image sensor of claim 15, wherein the comparator further comprises a common current source, the common current source being configured to supply bias current to the first input transistor and the second input transistor,
the first input transistor is coupled between the first cascode transistor and a common node coupled to the common current source, and
the second input transistor is coupled between the common node and the second output node.

17. The image sensor of claim 16, wherein the comparator further comprises:
a first switch configured to couple a gate of the first input transistor to the first output node during a predetermined time period; and
a second switch configured to couple a gate of the second input transistor to the second output node during the predetermined time period.

18. The image sensor of claim 16, wherein the comparator further comprises a second cascode transistor, and
one end of the second cascode transistor is coupled to the second output node and another end of the second cascode transistor is coupled to the second input transistor and a third output node configured to output a third signal based on the difference between the reference signal and the input signal.

19. The image sensor of claim 14, wherein the comparator further comprises a common current source, the common current source being configured to supply bias current to the first input transistor and the second input transistor,
the first input transistor is coupled between the first output node and a common node coupled to the common current source,
the second input transistor is coupled between the common node and the second output node, and
the first cascode transistor is coupled to one end of the first input transistor and the first output node.

20. A method for comparing signals of an image sensor including a comparator, the method comprising:
obtaining an input signal corresponding to a pixel signal and a reference signal corresponding to a lamp signal;
outputting a first output signal based on a difference between the reference signal and the input signal;
wherein the comparator comprises:
a first input transistor configured to receive the reference signal;
a second input transistor configured to receive the input signal;
a first load transistor configured to output the first output signal to a first output node based on the difference between the reference signal and the input signal; and
a first cascode transistor coupled to the first input transistor and the first output node.
